(19) United States
(12) Patent Application Publication
(10) Pub. No.: US 2011/0069531 A1
(43) Pub. Date: Mar. 24, 2011

(54) NONVOLATILE SEMICONDUCTOR STORAGE DEVICE AND METHOD OF MANUFACTURING THE SAME

(76) Inventors: Ryota ABURADA, Kanagawa (JP); Toshiya KOTANI, Tokyo (JP); Takafumi TAGUCHI, Kanagawa (JP); Chikaaki KODAMA, Kanagawa (JP)

(21) Appl. No.: 12/858,986

(22) Filed: Aug. 18, 2010

(30) Foreign Application Priority Data
Sep. 18, 2009 (JP) 2009-217787

(51) Int. Cl. G11C 11/00; H01L 21/02

(52) U.S. Cl. 365/148; 438/382; 257/E21.004; 365/210.1

(57) ABSTRACT

According to one embodiment, a method of manufacturing a nonvolatile semiconductor storage device includes a memory-cell forming step, a first wire forming step, and a second wire forming step. The memory-cell forming step is forming dummy memory cells arranged at a predetermined space apart from an end memory cell located at an end of a group of memory cells set in contact with the same first or second wire among the memory cells, the dummy memory cells having a laminated structure same as that of the memory cells and being set in contact with no second wire.

### CROSS-REFERENCE TO RELATED APPLICATIONS

This application is based upon and claims the benefit of priority from the prior Japanese Patent Application No. 2009-217787, filed on Sep. 18, 2009; the entire contents of which are incorporated herein by reference.

### FIELD

Embodiments described herein relate generally to a nonvolatile semiconductor storage device and a method of manufacturing the same.

### BACKGROUND

In the past, a flash memory is used as a representative of nonvolatile semiconductor storage devices. However, there is a limit in microminiaturization of the flash memory and processing for rewriting the flash memory is complicated. Therefore, in recent years, a variable resistance memory in which a variable resistance element is used as a memory cell is proposed as a nonvolatile semiconductor storage device replacing the flash memory.

As the variable resistance element, for example, a phase change memory element that changes resistance according a state change of crystallization/amorphization of a chalcogenide compound, a MRAM element that uses a resistance change due to a tunnel magneto-resistance effect, a memory element of a polymer ferroelectric RAM (PFRAM) in which a resistance element is formed by conductive polymer, a ReRAM element that causes a resistance change according to electric pulse application, and the like are known. In the variable resistance memory, a memory cell can be configured by a series circuit of the variable resistance element and a Schottkey diode. The shape of the memory cell is a columnar shape. A word line and a bit line are respectively connected to the lower surface and the upper surface of a column. In the variable resistance memory, because the shape of the memory cell is the columnar shape, memory cells can be laminated in a longitudinal direction. Therefore, the memory cells can be two-dimensionally arranged in a matrix shape. Moreover, a three-dimensional structure in which a plurality of memory cells are laminated in the longitudinal direction can also be realized.

In recent years, according to microminiaturization of a large scale integration (LSI), minimum line width on a semiconductor circuit is required to be length equal to or smaller than a half of light source wavelength of an exposure device mainly used for manufacturing currently. Because such microminiaturization is requested in these days, in the variable resistance memory, microminiaturization of a columnar pattern left in a matrix shape is also necessary in addition to microminiaturization of a line pattern and a hole pattern.

The columnar pattern is formed by, after laminating material layers included in the Schottkey diode and the variable resistance element and a hard mask layer, performing a photolithography process and an etching process. The columnar memory cells are arranged in a matrix shape at a dense period. A processing conversion error that occurs in the etching process is large at a period end where an opening angle is large. Therefore, in the memory cells located at the end, a taper occurs toward a direction in which the opening angle is wide. The size of the memory cell is large. In particular, in the memory cells located at the end, a phenomenon in which a diameter in a width direction of a lower layer wire is large occurs. As a result, the memory cells at the end formed on different lines are short-circuited. Short circuit occurs between the wires via the short-circuited memory cells.

### BRIEF DESCRIPTION OF THE DRAWINGS

FIG. 1 is a perspective view of a memory cell included in a nonvolatile semiconductor storage device according to an embodiment;

FIG. 2 is a perspective view of a part of a memory cell array included in a nonvolatile semiconductor storage device according to the embodiment;

FIG. 3 is a sectional view of a main part of the nonvolatile semiconductor storage device according to the embodiment;

FIG. 4 is of a plan view of a main part of an integrated circuit of the nonvolatile semiconductor storage device according to the embodiment;

FIG. 5 is a top view of a semiconductor wafer after memory cell MC processing in which dummy memory cells and dummy wires are not provided;

FIG. 6 is a top view of a semiconductor wafer after memory cell processing in the embodiment;

FIGS. 7A and 7B are sectional views of a manufacturing process for the nonvolatile semiconductor storage device according to the embodiment;

FIGS. 8A and 8B are sectional views of the manufacturing process for the nonvolatile semiconductor storage device according to the embodiment;

FIGS. 9A and 9B are sectional views of the manufacturing process for the nonvolatile semiconductor storage device according to the embodiment;

FIGS. 10A and 10B are sectional views of the manufacturing process for the nonvolatile semiconductor storage device according to the embodiment;

FIGS. 11A and 11B are sectional views of the manufacturing process for the nonvolatile semiconductor storage device according to the embodiment;

FIGS. 12A and 12B are sectional views of the manufacturing process for the nonvolatile semiconductor storage device according to the embodiment;

FIGS. 13A and 13B are sectional views of the manufacturing process for the nonvolatile semiconductor storage device according to the embodiment;

FIGS. 14A and 14B are sectional views of the manufacturing process for the nonvolatile semiconductor storage device according to the embodiment;

FIG. 15 is a plan view of a main part of an integrated circuit in a first modification of the embodiment;

FIG. 16 is a plan view of a main part of an integrated circuit in a second modification of the embodiment; and

FIG. 17 is a plan view of a main part of an integrated circuit in a third modification of the embodiment.

### DETAILED DESCRIPTION

In general, according to one embodiment, a method of manufacturing a nonvolatile semiconductor storage device includes a memory-cell forming step, a first wire forming step, and a second wire forming step. The memory-cell forming step is forming a plurality of columnar memory cells arranged in a matrix shape on a principal plane side of a semiconductor substrate and having a laminated structure. The first wire forming step is forming a plurality of first wires respectively set in contact with one bottom surfaces of a group of memory cells arranged on a straight line among the memory cells, the first wires being parallel to one another. The second wire forming step is forming a plurality of second wires respectively set in contact with the other bottom surfaces of the group of memory cells arranged on the straight line among the memory cells, the second wires being parallel to one another and crossing the first wires in the same plan view. The memory-cell forming step is forming dummy memory cells arranged at a predetermined space apart from an end memory cell located at an end of a group of memory cells set in contact with the same first or second wire among the memory cells, the dummy memory cells having a laminated structure same as that of the memory cells and being set in contact with no second wire.

Exemplary embodiments of a nonvolatile semiconductor storage device and a method of manufacturing the same will be explained below in detail with reference to the accompanying drawings. The present invention is not limited to the following embodiments.

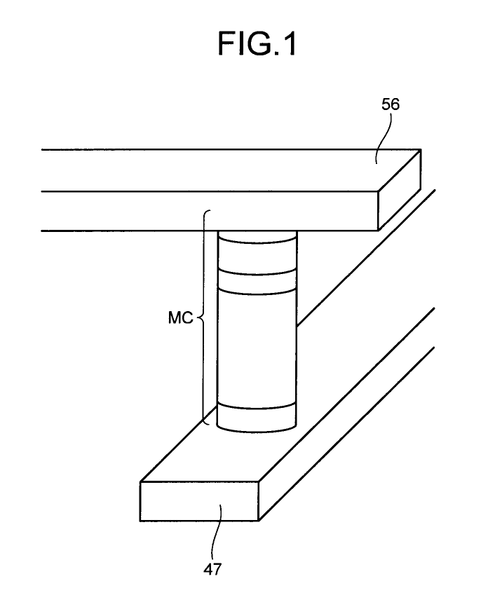

FIG. 1 is a perspective view of a memory cell included in a nonvolatile semiconductor storage device according to an embodiment.

As shown in FIG. 1, a memory cell MC included in the nonvolatile semiconductor storage device according to the embodiment has a columnar shape. The memory cell MC has a structure in which a diode element and a variable resistance element connected in series to the diode element are laminated. A word line 47 extends in a predetermined direction. A bit line 56 extends to cross the word line 47 in the same plan view. The memory cell MC is arranged to be sandwiched between the word line 47 and the bit line 56 in a crossing section of both the wires.

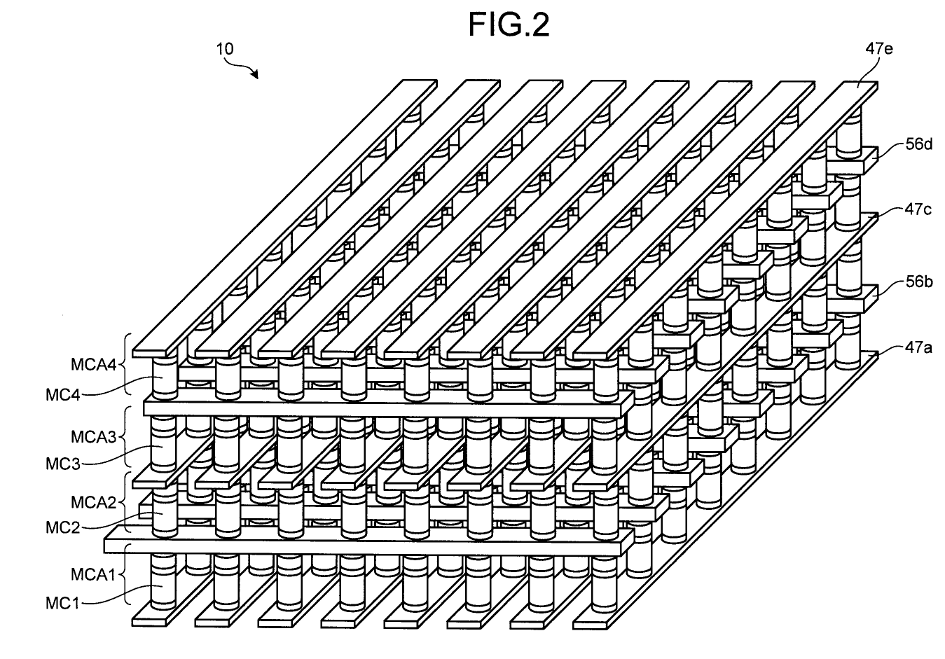

As shown in a perspective view of FIG. 2, the nonvolatile semiconductor storage device according to this embodiment has a three-dimensional structure in which a plurality of memory cell arrays MCA1 to MCA4 are laminated in a height direction of memory cells. In the memory cell arrays MCA1 to MCA4, memory cells MC are two-dimensionally arranged at an equal pitch in a matrix shape.

The memory cell array MCA1 includes a plurality of memory cells MC1. The memory cell array MCA2 includes a plurality of memory cells MC2 laminated on the memory cells MC1. The memory cell array MCA3 includes a plurality of memory cells MC3 laminated on the memory cells MC2. The memory cell array MCA4 includes a plurality of memory cells MC4 laminated on the memory cells MC3.

The nonvolatile semiconductor storage device includes a plurality of word lines 47a, 47c, and 47e parallel to one another. The nonvolatile semiconductor storage device includes bit lines 56b and 56d parallel to one another and crossing the word lines 47a, 47c, and 47e in the same plan view. The word lines 47a, 47c, and 47e are respectively set in contact with one bottom surfaces of a group of memory cells MC arranged on a straight line among a plurality of memory cells MC arranged in a matrix shape. The word lines 56b and 56d are respectively set in contact with the other bottom surfaces of the group of memory cells MC arranged on the straight line among the memory cells MC arranged in a matrix shape.

Among the memory cells MC, the memory cells MC1 of the memory cell array MCA1 in the bottom stage are set in contact with predetermined word lines among the word lines 47a on lower surfaces of the memory cells MC1 and set in contact with predetermined bit lines among the bit lines 56b on upper surfaces of the memory cells MC1. The memory cells MC2 of the memory cell array MCA2 are set in contact with predetermined bit lines among the bit lines 56b on lower surfaces of the memory cells MC2 and set in contact with predetermined word lines among the word lines 47c on upper surfaces of the memory cells MC2. The memory cells MC3 of the memory cell array MCA3 are set in contact with predetermined word lines among the word lines 47c on lower surfaces of the memory cells MC3 and set in contact with predetermined bit lines among the bit lines 56d on upper surfaces of the memory cells MC3. The memory cells MC4 of the memory cell array MCA4 are set in contact with predetermined bit lines among the bit lines 56d on lower surfaces of the memory cells MC4 and set in contact with predetermined word lines among the word lines 47e on upper surfaces of the memory cells MC4. The bit lines 56b and 56d are orthogonal to the word lines 47a, 47c, and 47e.

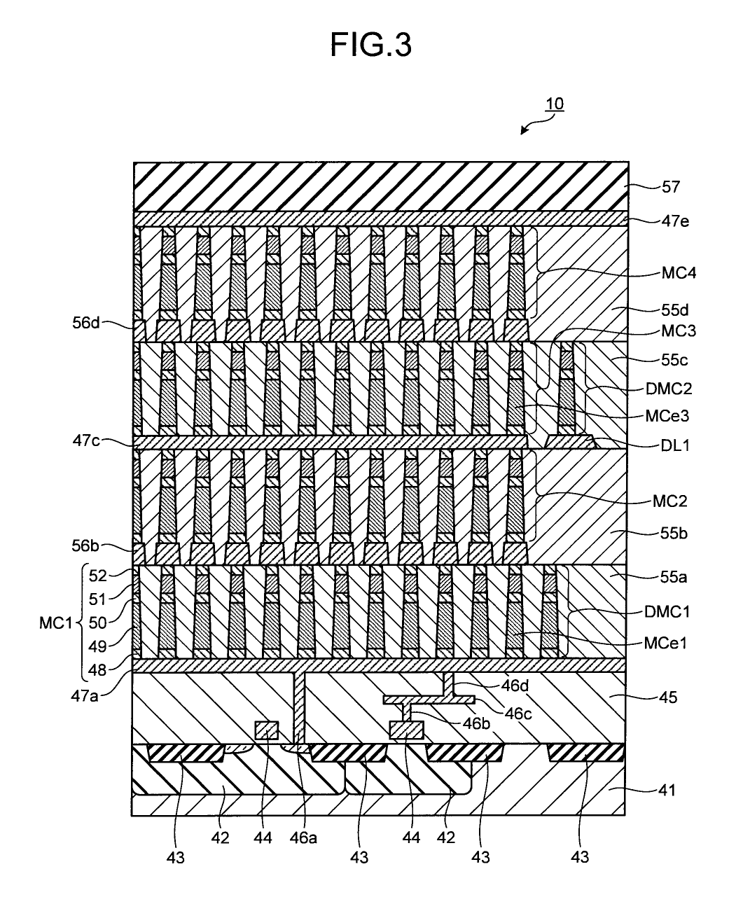

FIG. 3 is a sectional view of a main part of a nonvolatile semiconductor storage device 10 according to this embodiment. FIG. 3 is a sectional view of the nonvolatile semiconductor storage device 10 taken in a laminating direction along an extending direction of the word lines 47a, 47c, and 47e. FIG. 3 is a partial sectional view including end areas of memory cell arrays.

As shown in FIG. 3, a silicon substrate 41 includes wells 42. On the silicon substrate 41, impurity diffusion layers 43 and gate electrodes 44 of a transistor included in a peripheral circuit are located. An interlayer insulation film 45 formed of a multilayer insulation film such as a silicon oxide (SiO₂) film is deposited on the impurity diffusion layers 43 and the gate electrodes 44. In the interlayer insulation film 45, a via 46a reaching the surface of the silicon substrate 41, a via 46b reaching the gate electrode 44 of the transistor, a wire 46c connected to the via 46b, and a via 46d reaching the wire 46c are located as appropriate. On the interlayer insulation film 45, the word line 47a connected to the vias 46a and 46d is located. A material of the word line 47a is a low resistance metal such as tungsten (W).

The memory cells MC1 are arranged in an upper layer of the word line 47a. The memory cells MC1 has a laminated structure in which layers forming barrier metals 48, diode elements 49, first electrodes 50, variable resistance elements 51, and second electrodes 52 are laminated.

The barrier metals 48 included in the memory cells MC1 are located on the word line 47a. A material of the barrier metals 48 is any one of titanium (Ti) and titanium nitride (TiN) or both. The diode elements 49 such as Schottkey diodes are located on the barrier metals 48. A material of the diode elements 49 is, for example, a polysilicon film containing impurities.

The first electrodes 50, the variable resistance elements 51, and the second electrodes 52 are located in this order on the diode elements 49. A material of the first electrodes 50 is, for example, TiN. A material of the variable resistance elements 51 has a characteristic of causing a resistance change according to applied voltage. The material of the variable resistance element 51 is, for example, titanium oxide nitride (TiON). A material of the second electrodes 52 is, for example, TiN. The variable resistance elements 51 are, for example, phase change memory elements that change resistance according to a state change of crystallization/amorphization of a chalcogenide compound, MRAM elements that use a resistance change due to a tunnel magneto-resistance effect, memory elements of a polymer ferroelectric RAM (PFRAM) in which a resistance element is formed by conductive polymer, or ReRAM elements that cause a resistance change according to electric pulse application.

The memory cells MC1 are arranged in a matrix shape to form the memory cell array MCA1. An interlayer insulation film 55a is deposited among the memory cells MC1 adjacent to one another. The interlayer insulation film 55a is a multilayer or a single layer.

The bit lines 56b extending in a direction orthogonal to the word line 47a are located on the memory cells MC1. A material of the bit lines 56b is low-resistance metal such as W.

The memory cells MC2 including the barrier metals 48, the diode elements 49, the first electrodes 50, the variable resistance elements 51, and the second electrodes 52 in the same manner as the memory cells MC1 are located on the bit lines 56b. The memory cells MC2 are arranged in a matrix shape to form the memory cell array MCA2. An interlayer insulation film 55b is deposited among the memory cells MC2 adjacent to one another.

The word line 47c is located on the memory cells MC2. The memory cells MC3 having a laminated structure same as that of the memory cells MC1 and MC2 are located on the word line 47c. The bit lines 56d are located on the memory cells MC3. The memory cells MC4 having a laminated structure same as that of the memory cells MC1, MC2, and MC3 are located on the bit lines 56d. The word line 47e is located on the memory cells MC4. Interlayer insulation films 55c and 55d are respectively deposited among the memory cells MC2 adjacent to one another and among the memory cells MC3 adjacent to one another. A predetermined protection film 57 is located on the word line 47e in the top layer. In this way, the nonvolatile semiconductor storage device 10 having a multilayer structure including four layers is realized.

As shown in FIG. 3, the nonvolatile semiconductor storage device 10 includes a dummy memory cell DMC1, a dummy wire DL1, and a dummy memory cell DMC2. The dummy memory cells DMC1 and DMC2 are columnar. The dummy memory cells DMC1 and DMC2 have a laminated structure same as that of the memory cells MC1 to MC4. The dummy memory cells DMC1 and DMC2 have a laminated structure in which the diode element 49, the first electrode 50, the variable resistance element 51, and the second electrode 52 are laminated in this order.

One bottom surfaces of the dummy memory cells DMC1 and DMC2 are set in contact with no wire. In FIG. 3, upper surfaces of the dummy memory cells DMC1 and DMC2 are set in contact with no wire. Therefore, the dummy memory cells DMC1 and DMC2 do not perform a storage operation performed by the memory cells MC. Although not shown in the figure, the dummy memory cells DMC1 and DMC2 are arranged to correspond to all the memory cell arrays MCA1 to MCA4.

The dummy memory cells DMC1 and DMC2 are arranged adjacent to end memory cells located at ends of groups of memory cells set in contact with the same word lines 47a and 47b or the same bit lines 56b and 56d among the memory cells MC1.

For example, as shown in FIG. 3, the dummy memory cell DMC1 is arranged adjacent to a memory cell MCe1 located at an extension side end of the word line 47a among the memory cells MC on the word line 47a. The dummy memory cell DMC1 is arranged on the word line 47a same as the word line 47a on which the end memory cell MCe1 is arranged.

The dummy memory cell DMC2 is arranged adjacent to a memory cell MCe3 located at a line end side end of the word line 47c. The dummy memory cell DMC2 is arranged on the dummy wire DL1 formed on an extension line of the word line 47c.

The dummy wire DL1 is arranged on the same plane as the word line 47c. The dummy wire DL1 is arranged at a predetermined space apart from the word line 47c. As explained later, the dummy wire DL1 is formed in a process same as a process for forming the word line 47c.

As explained above, the nonvolatile semiconductor storage device 10 according to this embodiment has a configuration in which the dummy memory cells DMC1 and DMC2 are arranged at the ends of the groups of memory cells set in contact with the same word lines 47a and 47c or the same bit lines 56b and 56d among the memory cells MC. In other words, the nonvolatile semiconductor storage device 10 according to this embodiment has a configuration in which the dummy memory cells DMC1 and DMC2 are arranged adjacent to the end memory cells located at the ends of the memory cell arrays.

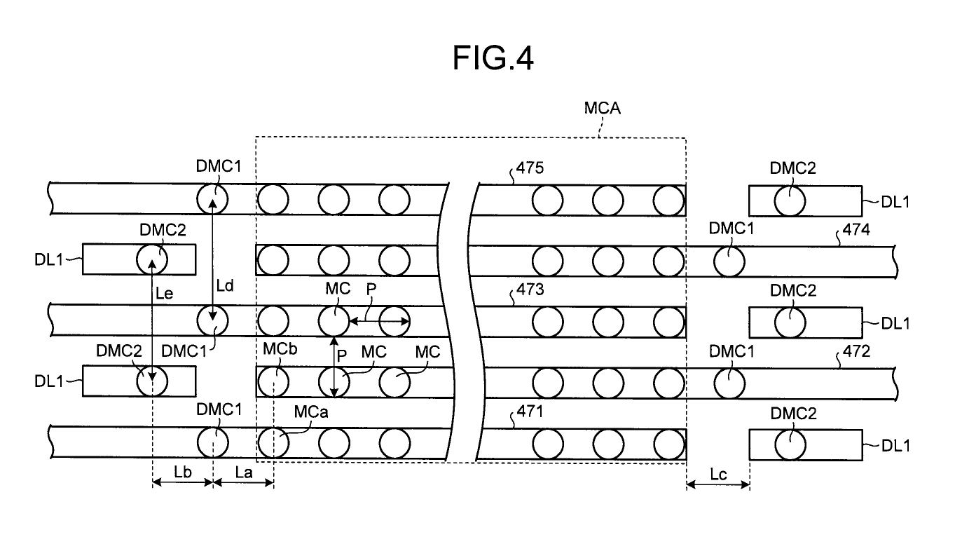

An arrangement relation among the dummy memory cells DMC1 and DMC2 and dummy wire DL1, the memory cells MC, and the wires is explained in detail below. FIG. 4 is an example of a plan view of a main part of an integrated circuit. In FIG. 4, a part of the word lines 47 (the word lines 47a, 47c, and 47e are generally referred to as the word lines 47) as wires included in, for example, a memory cell array MCA and the memory cells MC arranged on the word lines 47 is shown.

As shown in FIG. 4, word lines 471 to 475 arranged in parallel alternately extend in the right direction and the left direction in the figure, respectively. For example, the word line 471 located in the bottom in the figure extends from the right direction to the left direction in the figure. The word line 472 adjacent to the word line 471 on the upper side in the figure extends from the left direction to the right direction in the figure. The word lines 473 and 475 extend in the left direction in the same manner as the word line 471. The word line 474 extends in the right direction in the same manner as the word line 472. The word lines 471 to 475 are arranged a space same as wire width apart from one another.

The memory cells MC are arranged on the word lines 471 to 475 in a matrix shape at a pitch P. The memory cells MC are arranged in a matrix shape in this way to form the memory cell array MCA. Although not shown in FIG. 4, a plurality of bit lines extending in a direction orthogonal to the extending directions of the word lines 471 to 475 in the same plan view are arranged on the memory cells MC.

Dummy cell memories DMC1 are respectively arranged adjacent to end memory cells MCa located on an extension side of the word lines 471 to 475 among the memory cells MC located at ends of the memory cell array MCA. Because the dummy memory cells DMC1 are arranged on the extension side of the word lines 471 to 475, the dummy memory cells DMC1 are arranged on the word lines 471 to 475.

Dummy memory cells DMC2 are respectively arranged adjacent to end memory cells MCb located on line end side of the word lines 471 to 475 among the memory cells MC located at the ends of the memory cell array MCA. The dummy memory cells DMC2 are arranged on the line end side of the word lines 471 to 475, i.e., areas in which the word lines 471 to 475 are not originally formed, i.e., areas among the word lines 471 to 475 adjacent to one another.

Therefore, in this embodiment, as shown in FIG. 4, patterns of dummy wires DL1 are arranged in positions a predetermined space apart from the line end side ends of the word lines 471 to 475 on the same plane as the word lines 471 to 475. The dummy memory cells DMC2 are arranged on the dummy wires DL1. The dummy wires DL1 are connected to no wire and are floating. In a photo mask used for a wire forming process, an SRAF pattern can be arranged between line end sections of the word lines 471 to 475 and the dummy wires DL1 to prevent occurrence of regression of a resist at wire ends in an exposure process. An arrangement position and a size of the SRAF pattern on the photo mask can be any position and size as long as the position and the size are within ranges that satisfy rules for creating a mask.

The dummy memory cells DMC1 and DMC2 are arranged at a predetermined space apart from the end memory cells MCa and MCb to prevent expansion of a diameter in the width direction of lower layer wires, with which the end memory cells MCa and MCb are set in contact on lower surfaces thereof, in a diameter of the end memory cells MCa and MCb.

In the extending directions of the word lines 471 and 475, the dummy memory cells DMC1 are arranged at a space La, which is same as the pitch P among the memory cells MC, apart from the end memory cells MCa adjacent to the dummy memory cells DMC1 located on the same word lines 47a.

In the extending directions of the word lines 471 to 475, the dummy memory cells DMC2 arranged on the line end side of the word lines 471 to 475 are arranged a space Lb, which is the same as the pitch P among the memory cells MC, apart from the dummy memory cells DMC1 on the word lines 471 to 475 adjacent to the dummy memory cells DMC2 on the width direction side of the word lines 471 to 475 on which the dummy memory cells DMC2 are arranged. Therefore, in the extending directions of the word lines 471 to 475, the dummy memory cells DMC2 are arranged at a space twice as large as the pitch P among the memory cells MC apart from the memory cells MCb adjacent to the dummy memory cells DMC2.

In the extending directions of the word lines 471 to 475, the dummy wires DL1 are arranged at a predetermined distance Lc apart from the line end side ends of the word lines 471 to 475. The distance Lc is equal to or larger than a half of the pitch P. The dummy wires DL1 have width same as that of the word lines 471 to 475. In the width direction of the word lines 471 to 475, the dummy wires DL1 are alternately arranged among the word lines 471 to 475 at an interval same as an arrangement interval of the word lines 471 to 475. Therefore, a space Le in the width direction of lower layer wires among the dummy memory cells DMC2 arranged on the dummy wires DL1 is twice as large as the pitch P. The dummy memory cells DMC1 are respectively arranged on the extension lines of the word lines 471 to 475 alternately extended in the right direction and the left direction. Therefore, a space Ld in the width direction of the word lines among the dummy memory cell DMC1 is twice as large as the pitch P among the memory cells MC.

As explained above, in this embodiment, the dummy memory cells DMC1 and DMC2 are arranged at the predetermined space apart from the end memory cells MCa and MCb, whereby expansion of the diameter in the width direction of the lower layer wires of the end memory cells MCa and MCb in the memory cell MC forming process is prevented.

When dummy memory cells and dummy wires are not arranged, a diameter of end memory cells located at ends of memory cell arrays are actually expanded. FIG. 5 is a top view of a semiconductor wafer after memory cell MC processing in which dummy memory cells and dummy wires are not provided.

As shown in FIG. 5, expansion of a memory cell diameter does not occur concerning a memory cell MCt located in the center of the memory cell array. A diameter Dt in the width direction of the word lines 471 to 473 is a set diameter. On the other hand, a diameter De0 in the width direction of the word lines 471 to 473 in the end memory cells MCa and MCb located at ends of the memory cell arrays having an increased opening angle is markedly large compared with the diameter Dt of the memory cell MCt. In the end memory cells MCa and MCb, a taper occurs in a direction in which the opening angle is large. Therefore, a processing conversion error occurs after an etching process.

Further, fluctuation in a finished diameter of the memory cells MCa and MCb is large. As a result, when dummy memory cells and dummy wires are not arranged, in some case, the end memory cells MCa and MCb are short-circuited in an area S0 and short circuit occurs among wires via the short-circuited memory cells MCa and MCb.

On the other hand, in this embodiment in which the dummy memory cells DMC1 and DMC2 and the dummy wires DL1 are provided adjacent to the end memory cells located at the ends of the memory cells, the dummy memory cells DMC1 and DMC2 are located at memory cell array ends where the opening angle is large. Therefore, in the end memory cells MCa and MCb located further on the inner side than the dummy memory cells DMC1 and DMC2, size expansion due to the increase in the opening angle does not occur.

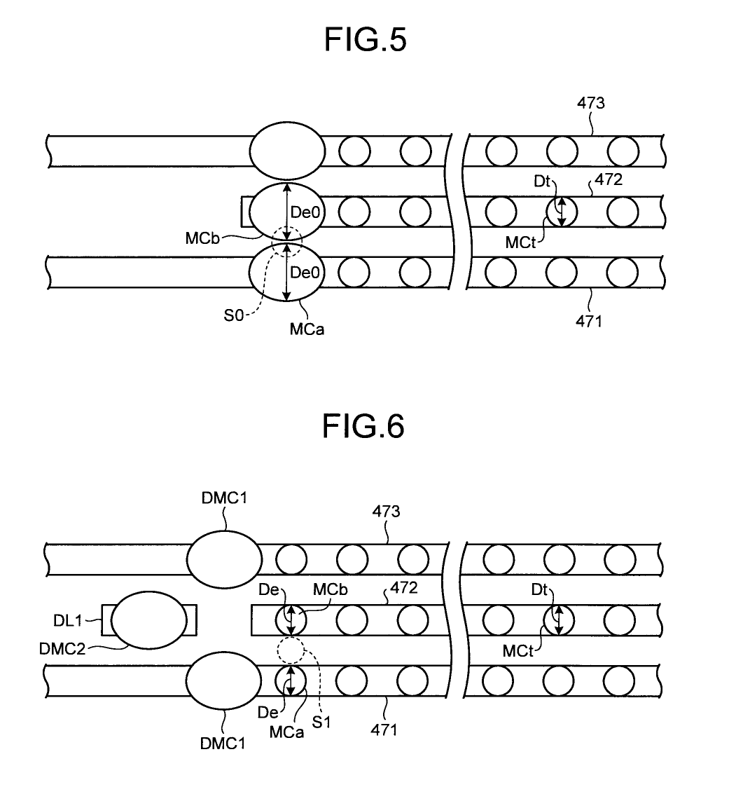

FIG. 6 is a top view of a semiconductor wafer after memory cell MC processing in this embodiment. As shown in FIG. 6, a diameter in the width direction of the word lines 471 to 473 of the dummy memory cells DMC1 and DMC2 arranged adjacent to the end memory cells MCa and MCb is markedly large compared with a diameter of the other memory cells MC. On the other hand, a diameter De of the end memory cells MCa and MCb is substantially the same as the diameter Dt of the memory cell MCt located in the center of the memory cell array.

Examples of target values of a memory cell diameter after the processes are explained below. A target value of a resist diameter after the photolithography process is 0.58 times as large as the pitch P. Concerning the memory cells MC in the centers of the memory cell arrays MCA, a target value of a memory cell diameter after the etching process is 0.63 times as large as the pitch P. Concerning the end memory cells MCa and MCb of the memory cell arrays MCA, a diameter in the width direction of lower layer wires is 0.73 times as large as the pitch P.

When the dummy memory cells DMC1 and DMC2 are actually formed according to the arrangement rules explained with reference to FIG. 4, the end memory cells MCa and MCb can be accurately formed with fluctuation in the diameter in the width direction of the lower layer wires of the end memory cells MCa and MCb suppressed to about ±15% in calculation with respect to the target value. As shown in FIG. 6, a diameter in a wiring direction of the end memory cells MCa and MCb does not expand exceeding the target value. In other words, the end memory cells MCa and MCb are formed to be spaced apart a distance equivalent to the area S1 shown in FIG. 6.

Therefore, contact of the end memory cells MCa and MCb can be surely prevented by forming the dummy memory cells DMC1 and DMC2. The diameter Dt of the memory cell MCt located in the center of the memory cell array has fluctuation of about ±18% in calculation with respect to the target value.

One bottom surfaces of the dummy memory cells DMC1 and DMC2 are connected to no wire. The dummy wire DL1 on which the dummy memory cell DMC2 is arranged is floating. Therefore, a diameter in the width direction of the lower layer wires of the dummy memory cells DMC1 and DMC2 is expanded. Even when the dummy memory cells DMC1 and DMC2 come into contact with each other, a normal operation of the nonvolatile semiconductor storage device 10 is not hindered.

Therefore, in this embodiment, occurrence of short-circuit between the end memory cells MCa and MCb in the area S1 can be surely prevented. Therefore, inter-wire short-circuit via the memory cells MCa and MCb can be prevented. In other words, in this embodiment, the dummy memory cells DMC1 and DMC2 are respectively arranged adjacent to the end memory cells MCa and MCb, whereby microminiaturization and normal operation of a nonvolatile semiconductor storage device can be surely realized.

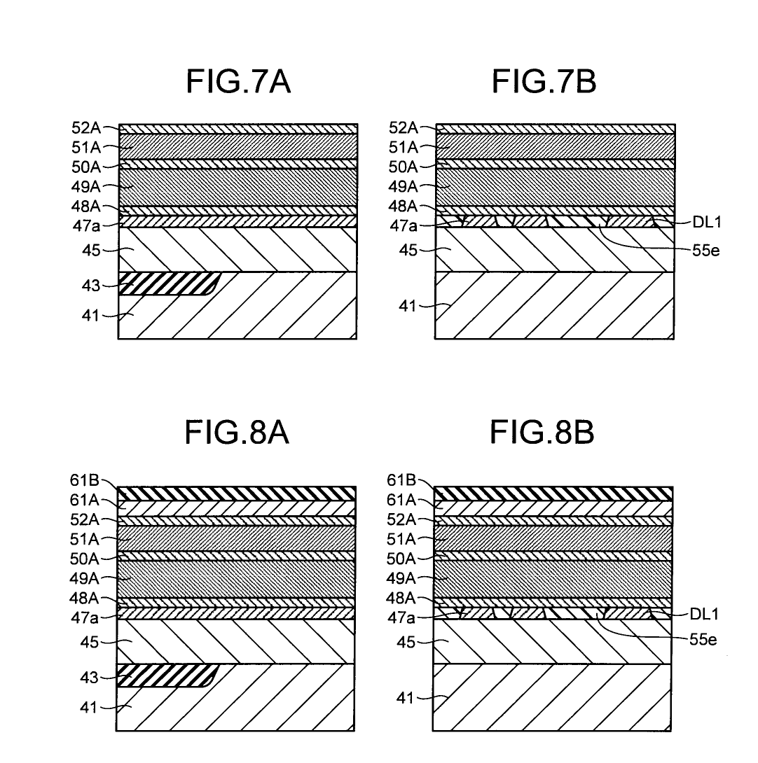

FIGS. 7A and 7B to FIGS. 14A and 14B are sectional views of a manufacturing process for a nonvolatile semiconductor storage device according to this embodiment. FIGS. 7A, 8A, 9A, 10A, 11A, 12A, 13A, and 14A are sectional views of a main part of the nonvolatile semiconductor storage device 10 taken along in the laminating direction along the extending direction of the word lines 47a, 47c, and 47e. FIGS. 7B, 8B, 9B, 10B, 11B, 12B, 13B, and 14B are sectional views of the main part of the nonvolatile semiconductor storage device 10 taken in the laminating direction along the extending direction of the bit lines 56b and 56d.

First, the wells 42, the gate electrodes 44, and the impurity diffusion layers 43 are formed on the silicon substrate 41. After a lower layer section of the interlayer insulation film 45 is deposited, predetermined planarization processing is performed to form the vias 46b and the wires 46c. After an upper layer section of the interlayer insulation film 45 is deposited and the predetermined planarization processing is performed, the vias 46a and 46d are formed. After a low-resistance metal film of W or the like is formed, the photolithography process and the etching process are performed to form the word lines 47a and the dummy wire DL1. After an interlayer insulation layer 55e is deposited between the word lines 47a and the dummy wire DL1, the predetermined planarization processing is performed (not shown). Subsequently, formation of a layer 48A to be the barrier metals 48, formation of a layer 49A to be the diode elements 49, formation of a layer 50A to the first electrodes 50, formation of a layer 51A to be the variable resistance elements 51, and formation of a layer 52A to be the second electrodes 52 are sequentially executed on the word lines 47a and the dummy wire DL1. A laminated structure shown in FIGS. 7A and 7B is formed by the process explained above.

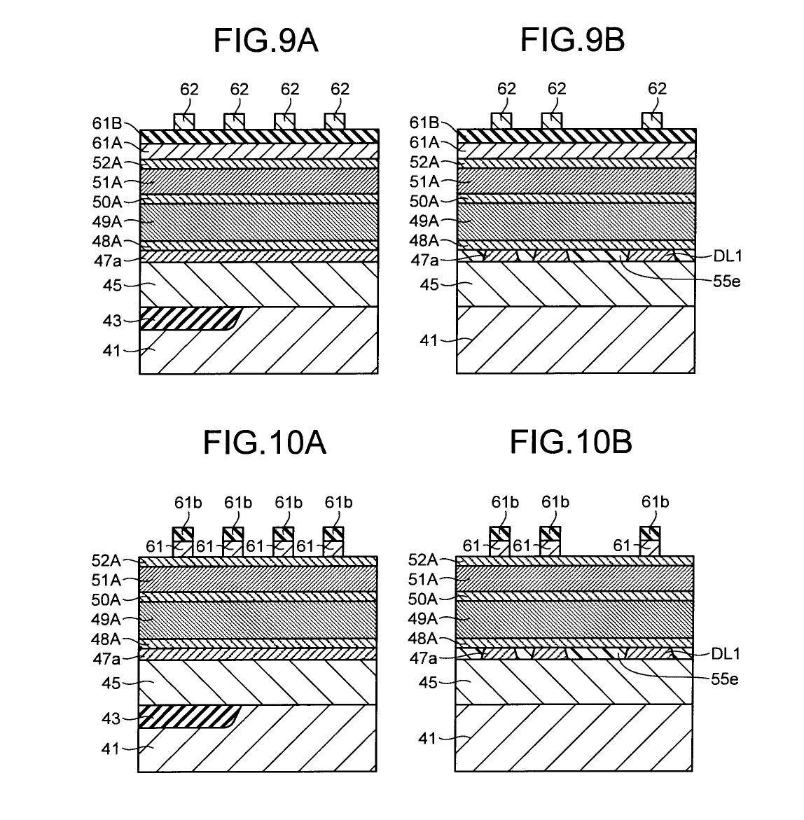

Subsequently, as shown in FIGS. 8A and 8B, a hard mask 61A and a hard mask 61B are deposited on the layer 52A. A predetermined reflection film is formed and, after a resist is coated thereon, the photolithography process is performed to form patterned resists 62 on the hard mask 61B as shown in FIGS. 9A and 9B. The resists 62 is formed in a matrix shape to correspond to the shape of the memory cells MC.

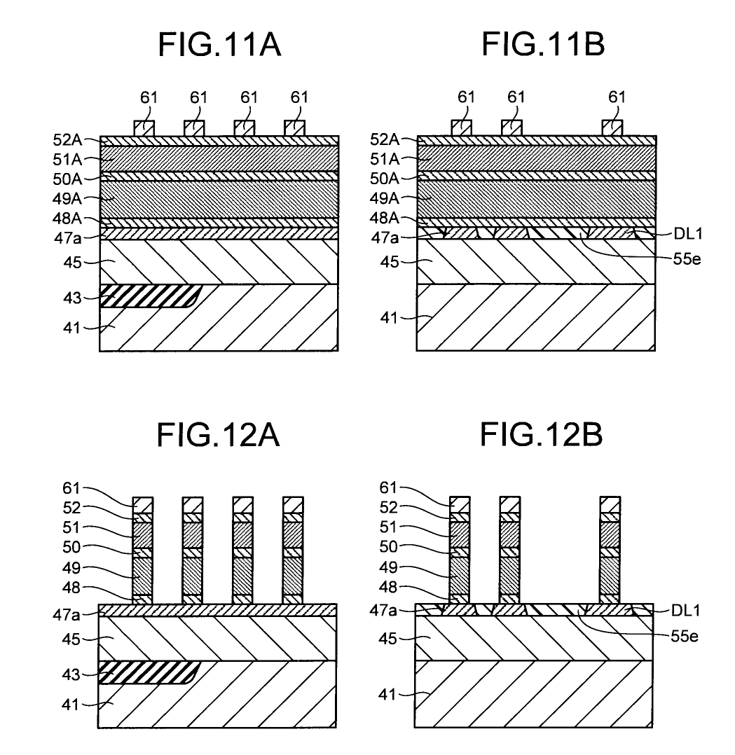

As shown in FIGS. 10A and 10B, the hard masks 61A and 61B are etched with the resists 62 as masks to form columnar hard masks 61 and 61b. As shown in FIGS. 11A and 11B, the resists 62 and the hard masks 61b are removed.

As shown in FIGS. 12A and 12B, the layers 48A to 52A are etched with the hard mask 61 as a mask to form the columnar barrier metals 48, the diode elements 49, the first electrodes 50, the variable resistance elements 51, and the second electrodes 52. Thereafter, the hard masks 61 are removed.

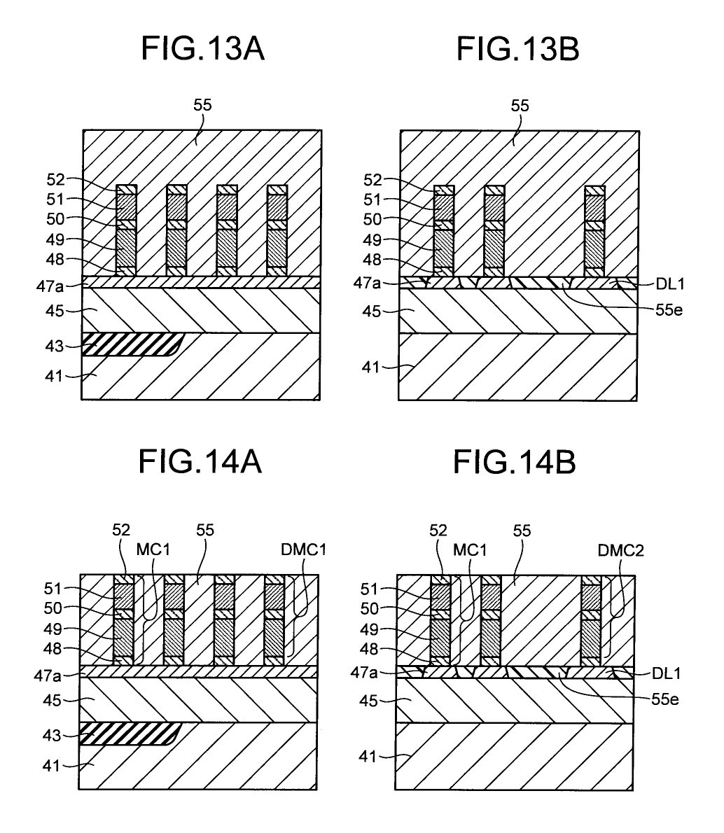

As shown in FIGS. 13A and 13B, an interlayer insulation film 55 is deposited to fill spaces among the columnar barrier metals 48, the diode elements 49, the first electrodes 50, the variable resistance elements 51, and the second electrodes 52.

As shown in FIGS. 14A and 14B, CMP processing is performed to planarize the interlayer insulation film 55 to the upper surfaces of the second electrodes 52. As a result, the dummy memory cells DMC1 and DMC2 can be formed together with the memory cells MC1 included in the memory cell array MCA1. The dummy memory cell DMC2 arranged in an area where the word lines 471 to 475 are not arranged is arranged on the dummy wire DL1 rather than right on the interlayer insulation film. The dummy memory cell DMC2 is arranged on a wiring layer in the same manner as the other memory cells MC. Therefore, collapse of the dummy memory cell DMC2 due to differences in a layer configuration and height can be prevented.

In the processes, the low-resistance metal film forming process (see FIGS. 7A and 7B) for forming wires to the CMP process (see FIGS. 14A and 14B) are repeated to laminate the memory cell arrays MCA2 to MCA4. After the word line 47e set in contact with the upper surfaces of the memory cells MC of the memory cell array MCA4 in the top layer is formed, the predetermined protection film 57 is formed. Consequently, the nonvolatile semiconductor storage device 10 can be formed.

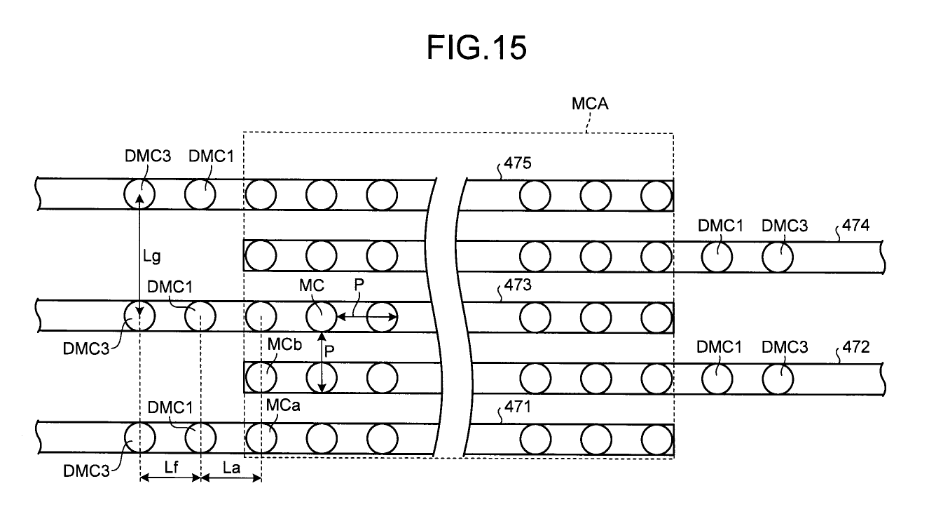

FIG. 15 is a plan view of a main part of an integrated circuit in a first modification of this embodiment. In FIG. 15, for example, a part of the word lines 47 as wires included in the memory cell array MCA and the memory cells MC arranged on the word lines 47 is shown.

As shown in FIG. 15, in the first modification, compared with the case shown in FIG. 4, dummy memory cells DMC3 are arranged instead of the dummy memory cells DMC2 and the dummy wires DL1.

The dummy memory cells DMC3 are arranged on the word lines 471 to 475, on which the dummy memory cells DMC1 are arranged, and adjacent to the dummy memory cells DMC1. The upper surfaces of the dummy memory cells DMC3 are set in contact with no wire in the same manner as the dummy memory cells DMC1. Therefore, the dummy memory cells DMC3 do not perform a storage operation in the same manner as the dummy memory cells DMC1.

The dummy memory cells DMC3 are arranged at a space Lf, which is a space same as the interval of the pitch P among the memory cells MC, from the dummy memory cell DMC1 in the extending directions of the word lines 471 to 475. Therefore, the dummy memory cells DMC1 and DMC3 and the end memory cells MCa are arranged at the pitch P in the extending directions of the word lines 471 to 475. In other words, in the first modification, as indicated by the dummy memory cells DMC1 and DMC3, a plurality of dummy memory cells are arranged adjacent to the end memory cells MCa at an interval same as the arrangement interval of the memory cells MC on the word lines 471 to 475.

The dummy memory cells DMC3 are arranged on the extension side on the word lines 471 to 475 alternately extending in the right direction and the left direction. Therefore, a space Lg in the width direction of lower layer wires among the dummy memory cells DMC3 is a space twice as large as the pitch P.

In this case, the dummy memory cells DMC1 prevent expansion of a diameter of the end memory cells MCa located on the same word lines and adjacent to the dummy memory cells DMC1. The dummy memory cells DMC3 prevent expansion of a diameter of the end memory cells MCb located on the word lines 471 to 475 adjacent to one another on the width direction side of the word lines 471 to 475 on which the dummy memory cells DMC3 are arranged. In this case, as in the embodiment, the memory cells MCa and MCb can be accurately formed with fluctuation in the diameter De of the memory cells MCa and MCb, near which the dummy memory cells DMC1 and DMC3 are formed, suppressed to about ±15% in calculation with respect to the target value.

When the dummy memory cells DMC1 and DMC3 are arranged adjacent to the end memory cells MCa in this way, as in the embodiment, expansion of a diameter in the width direction of the lower layer wires of the end memory cells MCa and MCb can be prevented.

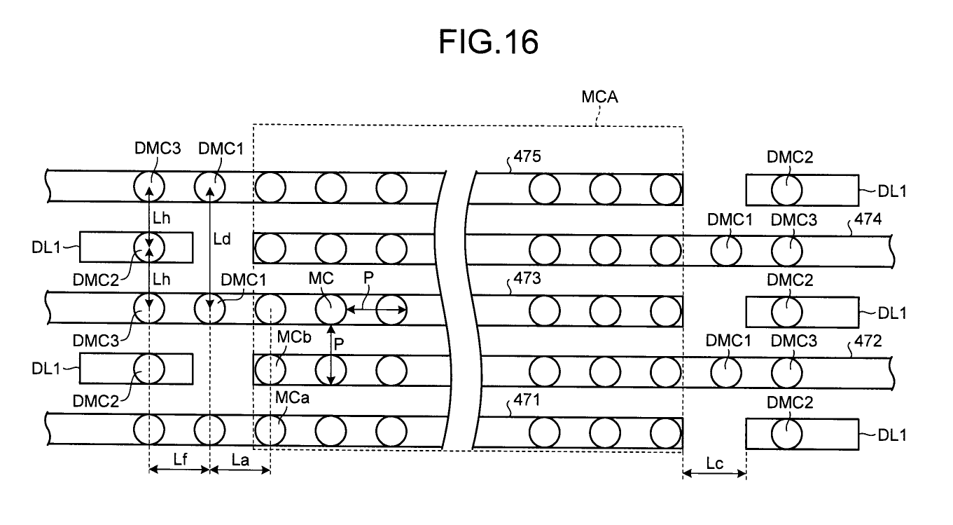

FIG. 16 is a plan view of a main part of an integrated circuit in a second modification of this embodiment. In FIG. 15, for example, a part of the word lines 47 as the wires included in the memory cell array MCA and the memory cells MC arranged on the word lines 47 is shown.

As shown in FIG. 16, in the second modification, compared with FIG. 4, the dummy memory cells DMC3 explained in the first modification are further arranged in addition to the dummy memory cells DMC1 and DMC2 and the dummy wires DL1.

The dummy memory cells DMC1, DMC2, and DMC3 and the dummy wires DL1 are arranged according to the arrangement rule explained in this embodiment and the first modification. The dummy memory cells DMC3 arranged adjacent to the dummy memory cells DMC1 and the dummy memory cells DMC2 arranged on the dummy wires DL1 adjacent to one another on the width direction sides of the word lines 471 to 475, on which the dummy memory cells DMC3 are arranged, are arranged at a space Lh, which is a space same as the pitch P among the memory cells MC, apart from each other.

In this case, expansion of a diameter of the end memory cells MCa located on the extension side of the word lines 471 to 475 is prevented by the dummy memory cells DMC1 located adjacent to the end memory cells MCa. Expansion of a diameter of the end memory cells MCb located on the line end side of the word lines 471 to 475 is prevented by the dummy memory cells DMC2 on the dummy wires DL1 located adjacent to the end memory cells MCb and the dummy memory cells DMC3 on the word lines 471 to 475 adjacent to the word lines 471 to 475 on which the end memory cells MCb are located.

When the dummy memory cells DMC1 and DMC3 and the dummy memory cells DMC2 on the dummy wires DL1 are arranged on the wires in this way, as in the embodiment, expansion of a diameter in the width direction of the lower layer wires of the end memory cells MCa and MCb can be prevented.

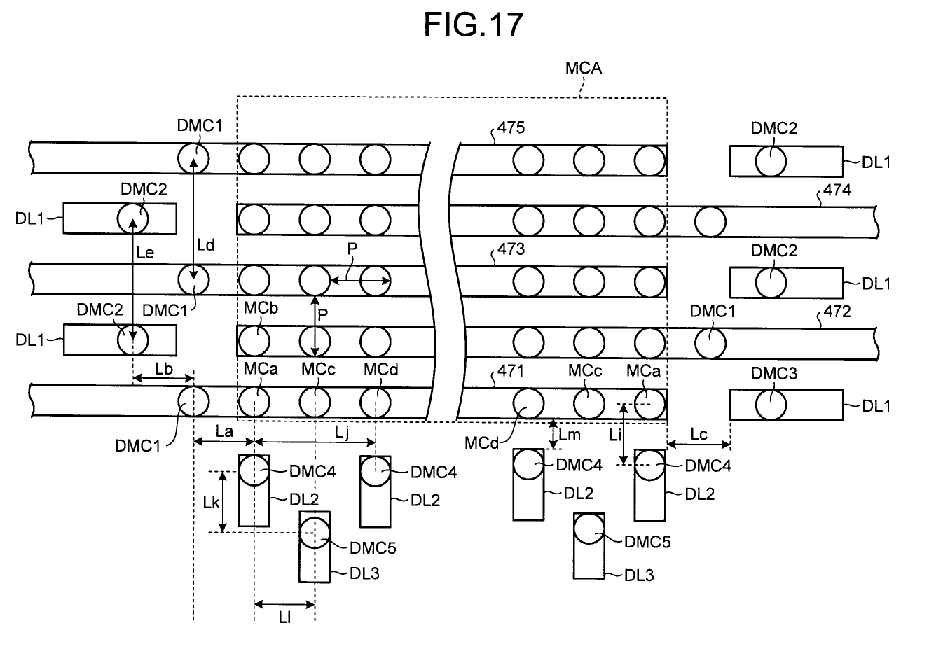

FIG. 17 is a plan view of a main part of an integrated circuit according to a third modification of this embodiment. In FIG. 17, for example, a part of the word lines 47 as the wires included in the memory cell array MCA and the memory cells MC arranged on the word lines 47 is shown.

As shown in FIG. 17, in the third modification, compared with the case shown in FIG. 4, dummy memory cells DMC4 and DMC5 are arranged not only on the extension side of the word lines 471 to 475 but also on straight lines orthogonal to the extending directions of the word lines 471 to 473.

The dummy memory cells DMC4 and DMC5 have a laminated structure same as that of the memory cells MC. Upper surfaces of the dummy memory cells DMC4 and DMC5 are set in contact with no wire in the same manner as the dummy memory cells DMC1, DMC2, and DMC3. Therefore, the dummy memory cells DMC4 and DMC5 do not perform a storage operation in the same manner as the dummy memory cells DMC1, DMC2, and DMC3.

The dummy memory cells DMC4 and DMC5 are arranged in an area where the word lines 47 are not formed on the outside of the memory cell array MCA. Therefore, in the third modification, dummy wires DL2 and DL3 are formed on the same plane as the word lines 471 to 473. The dummy wires DL2 and DL3 are arranged in positions a predetermined space apart from the end on the width direction side of the word line 471 on straight lines orthogonal to the extending directions of the word lines 471 to 473. The dummy wires DL2 and DL3 are formed in a process same as a process for forming the word line 471. In the third modification, the dummy memory cells DMC4 and DMC5 are arranged on the dummy wires DL2 and DL3. Patterns of the dummy memory cells DMC4 are arranged on the dummy wires DL2 and patterns of the dummy memory cells DMC5 are arranged on the dummy wires DL3.

The dummy memory cells DMC4 adjacent to the end memory cells MCa on the width direction side of the word line 471 are arranged at a space Li, which is a space same as the pitch P among the memory cells MC, apart from the end memory cells MCa. The dummy wires DL1, on which the dummy memory cells DMC4 are arranged, are arranged a predetermined distance Lm apart from the word line 471 in the width direction of the word line 471. Like the distance Lc, the distance Lm is equal to or larger than a half of the pitch P.

In the extending direction of the word line 471, the dummy memory cells DMC5 are arranged a space L1, which is a space same as the pitch P among the memory cells MC, apart from the dummy memory cells DMC4 adjacent to the dummy memory cells DMC5. In the width direction of the word line 471, the dummy memory cells DMC5 are arranged a space Lk, which is a space same as the pitch P among the memory cells MC, apart from the dummy memory cells DMC4 adjacent to the dummy memory cells DMC5. Therefore, in the width direction side of the word line 471, the dummy memory cells DMC5 is arranged a distance obtained by adding up the space Li and the space Lk, i.e., a space twice as large as the pitch P among the memory cells MC apart from memory cells MCc.

Memory cells MCd located adjacent to the memory cells MC and the dummy memory cells DMC4 adjacent to the memory cells MCd on the width direction side of the word line 471 are arranged a space the same as the pitch P among the memory cells MC apart from each other in the width direction of the word line 471. In the extending direction of the word line 471, the dummy memory cells DMC4 are arranged a space same as the pitch P among the memory cells MC apart from the dummy memory cells DMC5 adjacent to the dummy memory cells DMC4. Therefore, the dummy memory cells DMC4 are arranged a space Lj, which is a space twice as large as the pitch P among the memory cells MC, apart from each other in the extending direction of the word line 471.

As explained above, in the third modification, the dummy memory cells DMC4 and DMC5 and the dummy wires DL2 and DL3 are arranged not only on the line end side of the word line 471 but also on the width direction side of the word line 471 located at the end of the memory cell array MCA. Therefore, according to the third modification, it is also possible to prevent expansion of a diameter of the memory cells MC arranged on a wire at the end of the memory cell array MCA.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the sprit of the inventions. The accompanying claims and their equivalents are intended to cover such forms or modifications as would fall within the scope and spirit of the inventions.

What is claimed is:

1. A method of manufacturing a nonvolatile semiconductor storage device comprising:
forming a plurality of columnar memory cells arranged in a matrix shape on a principal plane side of a semiconductor substrate and having a laminated structure;
forming a plurality of first wires respectively set in contact with one bottom surfaces of a group of memory cells arranged on a straight line among the memory cells, the first wires being parallel to one another; and
forming a plurality of second wires respectively set in contact with the other bottom surfaces of the group of memory cells arranged on the straight line among the memory cells, the second wires being parallel to one another and crossing the first wires in a same plan view, wherein
the forming a plurality of columnar memory cells is forming dummy memory cells arranged at a predetermined space apart from an end memory cell located at an end of a group of memory cells set in contact with the same first or second wire among the memory cells, the dummy memory cells having a laminated structure same as that of the memory cells and being set in contact with no second wire.

2. The method of manufacturing a nonvolatile semiconductor storage device according to claim 1, wherein the memory cells are laminated in a height direction.

3. The method of manufacturing a nonvolatile semiconductor storage device according to claim 1, wherein the forming a plurality of columnar memory cells is forming, on the first wire, the dummy memory cells to be adjacent to the end memory cell a space same as an arrangement space of the memory cells apart from the end memory cell.

4. The method of manufacturing a nonvolatile semiconductor storage device according to claim 1, wherein
the forming a plurality of first wires is forming dummy wires arranged on a same plane as the first wires to be spaced apart from the first wires, and
the forming a plurality of columnar memory cells is forming the dummy memory cells on the dummy wires.

5. The method of manufacturing a nonvolatile semiconductor storage device according to claim 4, wherein the forming a plurality of first wires is forming, with respect to the first wires, the dummy wires at least on extension lines of the first wires or on straight lines orthogonal to an extending direction of the first wires.

6. The method of manufacturing a nonvolatile semiconductor storage device according to claim 1, wherein the memory cells have a laminated structure in which a diode element and a variable resistance element connected in series to the diode element are laminated.

7. A nonvolatile semiconductor storage device comprising:
a plurality of columnar memory cells arranged in a matrix shape on a principal plane side of a semiconductor substrate and having a laminated structure;
a plurality of first wires respectively set in contact with one bottom surfaces of a group of memory cells arranged on a straight line among the memory cells, the first wires being parallel to one another;
a plurality of second wires respectively set in contact with the other bottom surfaces of the group of memory cells arranged on the straight line among the memory cells, the second wires being parallel to one another and crossing the first wires in a same plan view;
dummy memory cells arranged at a predetermined space apart from an end memory cell located at an end of a group of memory cells set in contact with the same first or second wire among the memory cells, the dummy memory cells having a laminated structure same as that of the memory cells and being set in contact with no second wire.

8. The nonvolatile semiconductor storage device according to claim 7, wherein the memory cells are laminated in a height direction.

9. The nonvolatile semiconductor storage device according to claim 7, wherein the dummy memory cells are arranged on the first wires to be adjacent to the end memory cell a space same as an arrangement space of the memory cells apart from the end memory cell.

10. The nonvolatile semiconductor storage device according to claim 7, further comprising dummy wires arranged on a same plane as the first wires to be spaced apart from the first wires, wherein
the dummy memory cells are arranged on the dummy wires.

11. The nonvolatile semiconductor storage device according to claim 10, wherein the dummy wires are arranged, with respect to the first wires, at least on extension lines of the first wires or on straight lines orthogonal to an extending direction of the first wires.

12. The nonvolatile semiconductor storage device according to claim 7, wherein the memory cells have a laminated structure in which a diode element and a variable resistance element connected in series to the diode element are laminated.
